(19) United States
(12) Patent Application Publication
(10) Pub. No.: US 2011/0005926 A1
(43) Pub. Date: Jan. 13, 2011

(54) MAGNETRON ASSEMBLY

(75) Inventors: Neal W. Matuska, Plainview, MN (US); Joel T. Anderson, Cottage Grove, MN (US); Clifford L. Taylor, Northfield, MN (US); John R. German, Faribault, MN (US)

Correspondence Address: MOSER IP LAW GROUP / APPLIED MATERIALS, INC., 1030 BROAD STREET, SUITE 203, SHREWSBURY, NJ, 07702, US

(73) Assignee: APPLIED MATERIALS, INC.

(21) Appl. No.: 12/511,746

(22) Filed: Jul. 29, 2009

Related U.S. Application Data
(63) Continuation of application No. 10/919,791, filed on Aug. 17, 2004, now abandoned.

(51) Int. Cl. C23C 14/35

(52) U.S. Cl. 204/298.17

(57) ABSTRACT

A rotating magnetron assembly having a structure to reduce bearing degradation by substantially preventing the flow of current through the bearing using non-conductive materials or providing a low resistance current flow path or by allowing current to flow through the bearing in a way which prevents arcing between the various bearing components.

### BACKGROUND OF THE INVENTION

1. Field of the Invention

The present invention relates generally to an improved magnetron assembly and more specifically to a rotating magnetron assembly with means for reducing or eliminating bearing deterioration and degradation. The invention also relates to an improved bearing structure for use in a rotating magnetron assembly.

2. Description of the Prior Art

A rotating cathode or magnetron assembly includes a vacuum sputtering chamber, a rotatable target within the vacuum chamber and a drive shaft for rotating the target. The drive shaft is supported in a housing by a plurality of bearings and the vacuum chamber is sealed from the ambient atmosphere. A seal/bearing combination such as a ferro fluidic seal which includes both a bearing component and a seal component is positioned between the drive shaft and the housing to form and maintain the seal between the vacuum chamber and the ambient atmosphere.

Power to the rotating cathode may be provided either from a direct current (DC) source or an alternating (AC) source. Many cathode systems presently utilize an alternating current (AC) power source because of its ability to achieve a greater sputtering rate. When operating a cathode assembly using an AC power source, however, a couple of issues arise. First, as current, voltage and frequency increase, a phenomenon known as inductive heating can occur in various electrically conductive materials such as the bearings supporting the drive shaft and forming the seal around the drive shaft between the vacuum chamber and the ambient atmosphere. U.S. Pat. No. 6,736,948 addresses this issue by utilizing full ceramic bearings, non-inductive materials and non-metallic low drag rotational seal rings to eliminate inductive heating in the most critical areas surrounding the current path.

Second, as a result of rapidly changing current conditions in an AC operation, stray currents or eddy currents can be induced in the magnetron assembly. The current loops formed by these induced stray or eddy currents can cause pitting, fluting or other significant damage to the bearings and other components of the seal and bearing means. This degradation of the bearing, and particularly the balls or rollers in the ball or roller bearings, results in a significantly shortened bearing and magnetron assembly life and can lead to other cathode operation problems as well.

Accordingly, there is a need in the art to address this bearing damage and degradation issue which occurs during AC operation of a sputtering magnetron assembly.

### SUMMARY OF THE INVENTION

In accordance with the present invention, means are provided for eliminating or substantially reducing the bearing degradation which occurs during AC operation of a sputtering cathode and in particular, eliminating or reducing such bearing degradation and reducing inductive heating in an efficient and cost effective way.

As rotary magnetron sputtering systems have advanced, newer AC power supplies for such systems have provided improved arc suppression and control circuitry. When these systems are implemented, they can result in rapidly changing current amplitudes on the load side of the power supply. Arcing within the vacuum chamber itself and other process conditions during start up or burn in can also contribute to changing current amplitudes. It is believed that these rapidly changing currents induce stray currents or eddy currents in the magnetron assembly. The current loops formed by these stray currents can cause significant damage to bearings in the magnetron assembly and can shorten the life of the assembly. In accordance with the present invention, it has been discovered that such damage to the bearings can be eliminated or substantially reduced by interrupting the induced current paths with an insulating material which prevents current flow through the bearings or by providing a low resistance electrical conductive flow path in close association with the bearings so that any induced current flows through these low resistance paths rather than through or across the bearings. With either of these approaches, inductive heating can be substantially reduced by water cooling of the main housing and/or the bearing/seal between the housing and the drive shaft.

One specific structural solution to this problem is to provide a hybrid bearing between the drive shaft and the housing. Such a hybrid bearing may include either a bearing race of a conductive material and a bearing ball or roller of a non-conductive material or a bearing race of a non-conductive material and a bearing ball or roller of a conductive material. With this structure, current is substantially prevented from passing through the bearing (and thus arcing between the race and the ball or roller) where it can cause pitting, fluting or other degradation of the bearing.

A further embodiment is to provide insulating sleeves on the inner or outer race of the bearing to preclude the stray or eddy currents from passing through the bearing. In this structure, both the bearing race and the bearing balls or rollers could be constructed from a conductive material.

A further embodiment is to provide a plain sleeve bearing of non-conductive material between the rotating drive shaft and the fixed housing. Because such a bearing is constructed of a non-conductive material, it would prevent any of the stray eddy currents from passing through the bearing and thus causing pitting, fluting or other bearing degradation.

A further embodiment is to provide electrically conductive brushes or other low resistance electrical conductive flow paths in close association with the bearings. In such a structure, the current preferentially flows through these brushes or low resistance paths rather than through the bearings.

A still further embodiment is to provide a bearing with a conductive (rather than a conventional non-conductive) grease between the bearing race and the bearing balls or rollers. In conventional bearings with conventional dielectric (non-conductive) grease, to the extent current flows through the bearings, arcing occurs as the current flows from the race to the ball or roller across the dielectric grease. This arcing can cause pitting, fluting or other bearing degradation. By making the grease conductive, arcing and thus bearing degradation is eliminated or substantially reduced.

Accordingly, the solution to bearing degradation in accordance with the present invention is to either preclude the flow of current through the bearing structure by the use of non-conductive materials or by providing a low resistance current flow path in close association with the bearings or allow the current to flow through the bearings in a way which prevents arcing between the bearing race and the bearing balls or rollers.

Accordingly, it is an object of the present invention to reduce or eliminate bearing degradation in a rotary magnetron sputtering system.

These and other objects of the present invention will become apparent with reference to the drawings, the description of the preferred embodiment and the appended claims.

### DESCRIPTION OF THE DRAWINGS

FIG. 1 is a view, partially in section, of a rotary magnetron sputtering assembly with a horizontally positioned target.

FIG. 2 is a view, partially in section, of a rotary magnetron sputtering assembly with a vertically positioned target.

FIG. 3 is a cross-sectional view of the ferro fluidic seal in accordance with the present invention.

FIGS. 4A and 4B are side and sectional views, respectively, of a single ball bearing configuration in accordance with the present invention.

FIGS. 5A and 5B are side and sectional views, respectively, of a double ball bearing configuration in accordance with the present invention.

FIG. 6 is a sectional view of a bearing configuration with non-conductive sleeves in accordance with the present invention.

FIG. 7 is a sectional view of a further embodiment of a bearing configuration in accordance with the present invention.

FIG. 8 is a sectional view of a further bearing configuration in combination with a conductive element for providing a current bypass.

FIG. 9 is a sectional view of a further embodiment of a ferro fluidic bearing/seal in accordance with the present invention.

FIG. 10 is comprised of FIGS. 10A and 10B in which FIG. 10A is a sectional view of a further embodiment of a ferro fluidic bearing/seal in accordance with the present invention and FIG. 10B is a sectional view as viewed along the section line 10B-10B of FIG. 10A.

FIG. 11 is a sectional view of a further embodiment of a bearing seal in accordance with the present invention.

FIG. 12 is a view, similar to FIG. 1, showing water cooling means for the bearing/seal member.

### DESCRIPTION OF THE PREFERRED EMBODIMENT

The present invention relates generally to a rotary magnetron sputtering or cathode assembly and more specifically to such an assembly incorporating means for preventing or substantially reducing bearing degradation and thus lengthening the bearing and assembly life. Such means includes means for either electrically isolating the various bearings between the drive shaft and housing to interrupt or substantially reduce any stray or eddy current flow through the bearing or providing a conductive bearing grease between the race and bearing member to eliminate or substantially reduce any arcing resulting from current flow through the bearing. Such means may be utilized by itself or in combination with means for addressing the inductive heating issue by water cooling the housing and/or bearing seal.

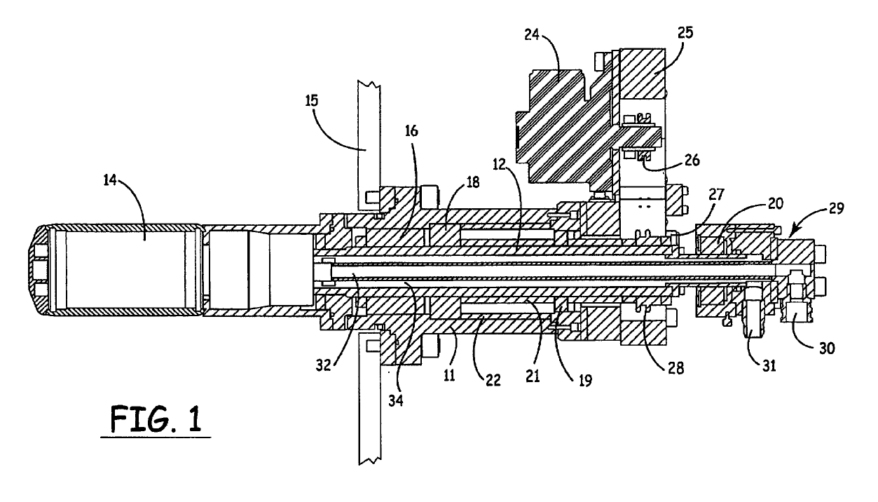

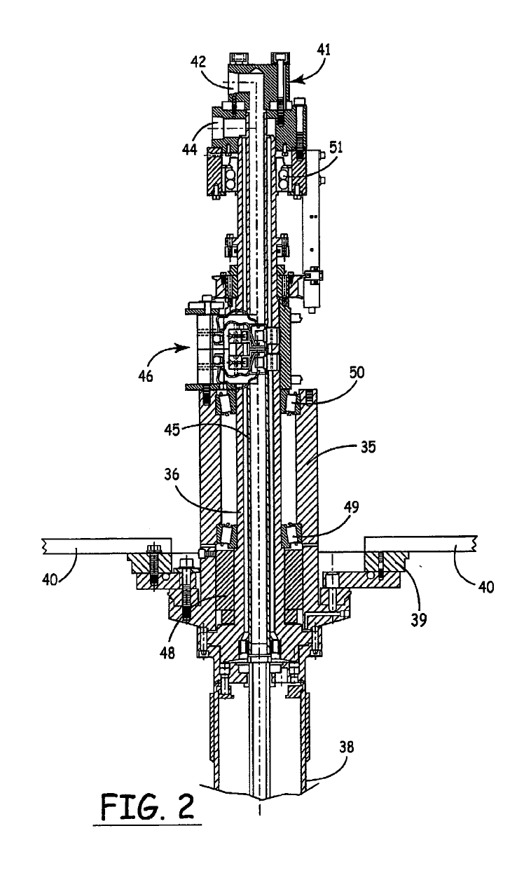

The various bearing configurations in accordance with the present invention have particular application to alternating current (AC) rotary magnetron sputtering assemblies. Examples of rotary magnetron assemblies to which the present invention is applicable include the assemblies disclosed in U.S. Pat. Nos. 5,100,527, 5,200,049 and 6,736,948, among others. The disclosures of these patents are incorporated herein by reference. Two rotating magnetron assemblies are shown in FIGS. 1 and 2, with FIG. 1 showing a magnetron sputtering assembly with a horizontally positioned target and FIG. 2 showing a magnetron sputtering assembly with a vertically oriented target.

With reference to FIG. 1, the sputtering assembly includes a main housing 11, a drive shaft 12 and a cathode 14 comprising a target of sputterable material. The main housing 11 is mounted to a vacuum chamber wall 15 which defines a vacuum chamber surrounding the cathode or target 14. The drive shaft 12 is a generally hollow, cylindrical structure which is supported for rotation within the housing 11 by a plurality of bearings 16, 18, 19 and 20. In the embodiment shown in FIG. 1, the bearing 16 is a ferro fluidic combination bearing and seal, and bearings 18, 19 and 20 are ball bearings. The specific structure of the bearings 16, 18, 19 and 20 will be discussed in greater detail below. A pair or inner and outer bearing spacing sleeves 21 and 22, respectively, are provided between the bearings 18 and 19 and between the drive shaft 12 and housing 11 to maintain such bearings in proper spaced relationship.

The target 14 is connected with the drive shaft 12 for rotation therewith. The shaft 12 is rotated relative to the housing 11 by a drive assembly which includes the gear box 24, the gear box housing 25 and the drive and drive shaft sprockets 26 and 28, respectively. Power, preferably AC power, is delivered to the cathode 14 via the brushes 27.

The housing 11 includes a water union assembly or housing 29 which is provided at the end of the drive shaft 12 opposite the cathode 14. The water union assembly 29 functions to provide cooling water or other cooling fluid to the interior of the cathode 14. The assembly 29 includes a water inlet 30 and a water outlet 31. During operation, cooling water or other cooling fluid is introduced through the water inlet 30 into the water feed tube 32 which delivers the cooling water to the interior of the cathode 14. The water is then returned through the water passage 34 between the feed tube 32 and the drive shaft 12 to the water outlet 31.

FIG. 2 is a further embodiment of a rotary magnetron sputtering assembly in which the cathode or target is vertically oriented as shown. The magnetron sputtering assembly of FIG. 2 includes a main housing 35, a rotatable drive shaft 36 and a cathode 38 comprising a target of sputterable material connected with the drive shaft 36 for rotation therewith. The main housing 35 includes a mounting flange 39 which is mounted to a wall 40 defining the vacuum chamber. As with the magnetron sputtering assembly of FIG. 1, the housing 35 includes a water union assembly or housing 41 at the end of the drive shaft 36 opposite the cathode 38. The water union assembly 41 includes a water inlet 42 and a water outlet 44. The water inlet 42 is connected with a water feed tube 45 for directing cooling water or other fluid to the interior of the cathode 38. The water is then returned through the area between feed tube 45 and the housing 35 where it exits through the water outlet 44.

AC power is provided to the cathode 38 via the AC power connection 46. The drive shaft 36 is rotatably mounted within the housing 35 by the combination bearing/seal member 48 and the bearing members 49, 50 and 51. In the preferred embodiment, the combination bearing/seal member 48 is a ferro fluidic seal, the bearing members 49 and 50 are tapered roller bearings and the bearing 51 is a double ball bearing. The details of these bearings 48, 49, 50 and 51 will be described in greater detail below.

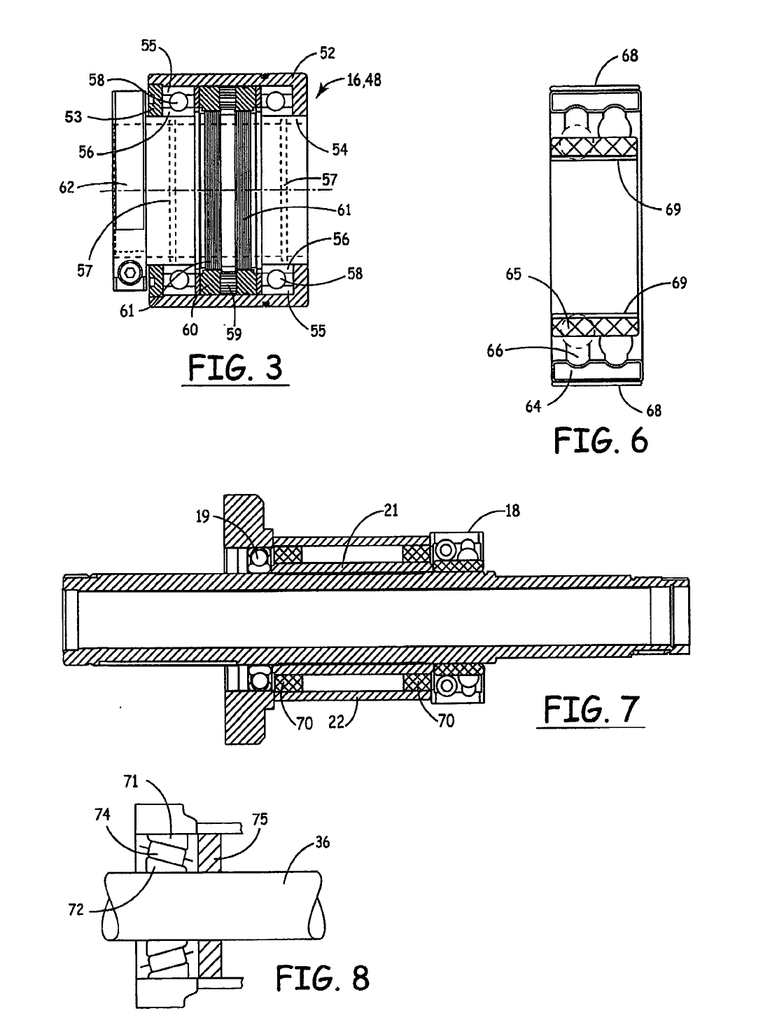

FIG. 3 is a cross-sectional view of a ferro fluidic seal of the type shown in the magnetron sputtering assemblies of FIGS. 1 and 2 and identified by the reference characters 16 and 48, respectively. The ferro fluidic seal 16,48 of FIG. 3 includes an outer race or housing 52 and an inner race or shaft 54. The seal 16,48 includes a pair of ball bearings, each including an outer race 55 connected with the housing 52 and an inner race 56 connected with the inner shaft 54. A plurality of balls 58 are positioned between the races 55 and 56 in a conventional manner. In accordance with the present invention, either the outer race 55, the inner race 56 or the ball 58 is constructed of a non-conductive material such as ceramic, with the remaining members constructed of a conventional electrically conductive material. With one of the members 55, 56 and 58 constructed of a non-conductive material, flow of electrical current such as that created by stray or eddy currents through the bearing is eliminated or substantially reduced.

The seal portion of the combination bearing/seal 16,48 is positioned between the bearing members and is comprised of a magnet 59 and an annular ring of a bipolar material 60 on each side of the magnet 59. As is conventional in ferro fluidic seals, the inner anular edge of the members 60 and corresponding outer surface portion of the inner shaft 54 are provided with a plurality of grooves 61. These grooves are provided with a ferro fluidic liquid material which is retained within the grooves 61 by the magnet 59 and which function to form a seal between the fixed members 60 and the rotating inner shaft 54. A threaded end cap 57 is threadedly received by the housing 52 to retain the bearing and seal elements. The inner shaft 54 is connected with the drive shaft 12,34 (FIGS. 1 and 2) via the clamp or collar 62. A pair of O ring seals 57,57 is provided between the inner shaft 54 and the drive shaft 12,36 (FIGS. 1 and 2).

As an alternative to one of the bearing elements 55, 56 and 58 being constructed of a non-conductive material, the inner shaft 54 can be constructed of a non-conductive material such as peek plastic or other non-conductive synthetic or other material. With this structure, any stray or eddy currents such as that generated by changes in current amplitude are prevented from passing through the bearings within the seal 16,48. The housing 52 may also be constructed of a non-conductive material, or provided with a non-conductive coating, to prevent current from passing through the bearings.

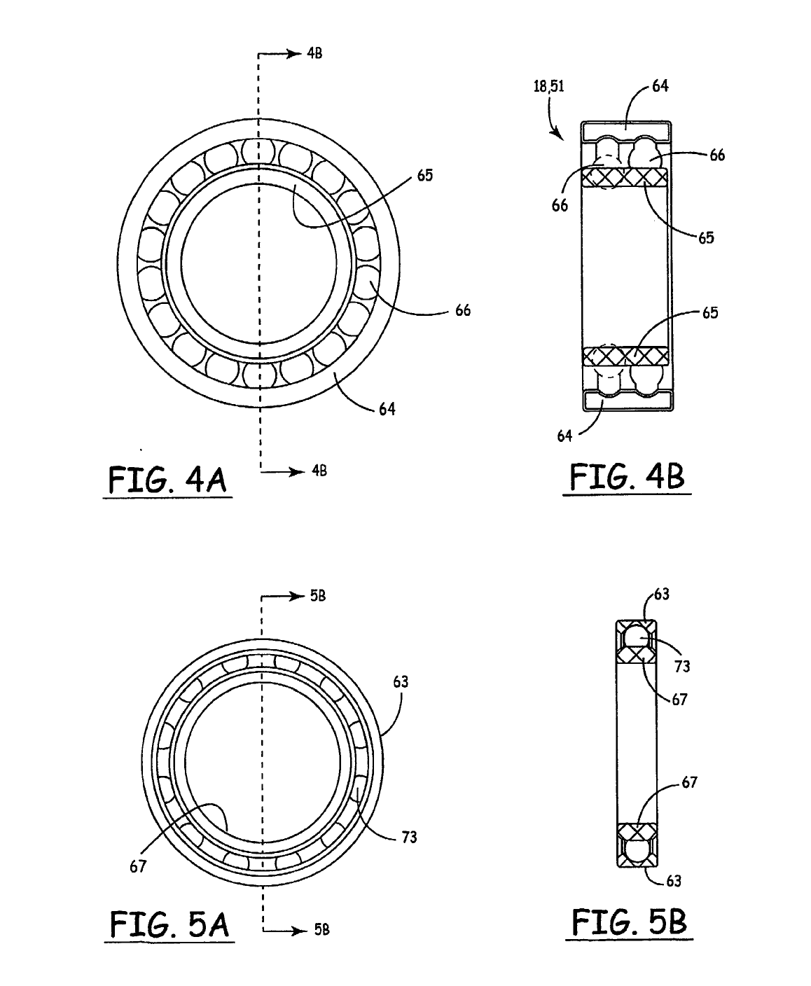

FIGS. 4A and 4B show a double ball bearing such as that utilized and illustrated in FIG. 1 as bearings 18 and 20 and in FIG. 2 as bearing 51. The bearing shown in FIGS. 4A and 4B includes an outer race 64, an inner race 65 and two sets of balls 66 positioned between the inner and outer races 64, 65 in a conventional manner. As is standard in bearing construction, the balls 66,66 are circumferentially staggered relative to one another. In accordance with the invention, either the outer race 64, or the inner race 65 or the balls 66 are constructed of a non-conductive material such as ceramic, with the remaining elements being constructed of an electrically conductive material. With such a structure, any passage of electrical current such as that created by eddy currents or the like through the bearing is eliminated or substantially reduced. This precludes any arcing between either of the races 64 and 65 and the balls 66, thus preventing or substantially reducing any degradation of the bearings 18, 20 and 51.

The bearing 19 of FIG. 1 is a single ball bearing which shown in FIGS. 5A and 5B. The bearing 19 includes an outer race 63, an inner race 67 and a plurality of balls 73 positioned between the races 63 and 67 in a conventional manner. In accordance with the present invention, the single ball bearing 19 is similar in construction to that of FIG. 4 in that either the outer race 63, the inner race 67 or the balls 73 are constructed of a non-conductive material, with the remaining members being constructed of a conductive material. Such structure will preclude or substantially eliminate the passage of stray electrical currents through the bearing, and thereby increase the bearing and system life.

FIG. 6 shows a double ball bearing structure similar to the bearing structure of FIG. 4B, but with either a non-conductive sleeve or coating 68 formed on the outer surface of the outer race 64 or a non-conductive inner sleeve or coating 69 formed on the inner surface of the inner race 65, or both. With this structure, the outer sleeve or coating 68, or the inner sleeve or coating 69, or both, prevent the passage of currents, such as eddy currents, through the bearing. Thus, with the structures shown in FIG. 6, all elements of the bearing, including the outer race 64, the inner race 65 and the balls 66 can be constructed of a conductive material. Similar non-conductive sleeves or coatings can be provided for the single ball bearing structures of FIGS. 5A and 5B.

A further means for preventing or substantially reducing the flow of any stray current through the bearings is shown in FIG. 7. This means includes providing a pair of annular grounding brushes 70, 70 between the conductive spacing sleeves 21 and 22 of FIG. 1 in close association with the bearings 18 and 19. Such sleeves 21 and 22 are positioned between the bearings 18 and 19 as shown in FIG. 7 and also in FIG. 1 to maintain proper spacing between the bearings 18 and 19. By providing a low resistance conductive bridge between the sleeves 21 and 22 in the form of a pair of conductive brushes 70,70, any stray current, such as eddy currents created by the changing power source, will flow through the brushes 70,70 rather than the bearings 18 and 19, thereby protecting the bearings 18 and 19. As shown, the brushes 70,70 are adjacent to or in close association with the bearings 18 and 19 so that any current in the area preferentially flows through the brushes 70,70 rather than through the bearings 18 and 19.

As shown in FIG. 8, similar concepts can be utilized with respect to the tapered roller bearings 49 and 50 of FIG. 2. Specifically, each such bearing 49 and 50 includes an outer race 71, an inner race 72 and a plurality of rollers 74 captured between the inner and outer races 71,72 in a conventional manner. To eliminate or substantially reduce the flow of any stray electrical current through such bearings, either the outer race 71, the inner race 72 or the rollers 74 can be constructed of a non-conductive material, with the remaining elements being constructed of conductive material. Further, the outer surface of the outer race 71 or the inner surface of the inner race 72, or both of these roller bearings 49 and 50 could be provided with a sleeve or coating of non-conductive material such as that shown in FIG. 6 to preclude or substantially reduce any flow of current through the bearings. Still further, electrically conductive grounding brushes 75 or similar conductive materials can be positioned adjacent to or in close association with the bearings 49 and 50 as shown in FIG. 8 so that any stray electrical current is conducted preferentially through this low resistance path rather than through the bearing.

Still further, a non-conductive coating can be applied to the outer surface of the drive shafts 12 and 36 (FIGS. 1 and 2) in the area of the bearings. Alternatively, a non-conducting coating can be applied to the inner surface of the housings 11 and 35 and the cooling water unions 29, 41 (FIGS. 1 and 2) in the area of the bearings. Preferably, such coatings are relatively thin, on the order of 10 thousandths of an inch or less.

A further embodiment in accordance with the present invention is to pack the bearings with a conductive bearing grease so that such grease is between the inner and outer races and the balls or rollers between such races. With a conductive bearing grease, any arcing resulting from the passage of stray currents through the bearings from the races to the balls or rollers is eliminated or substantially reduced.

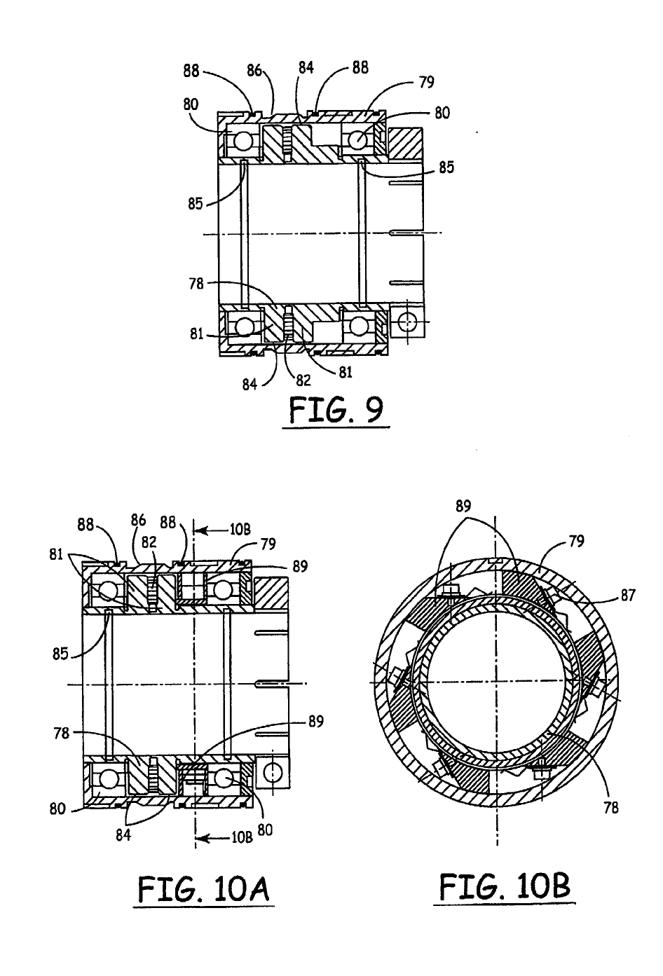

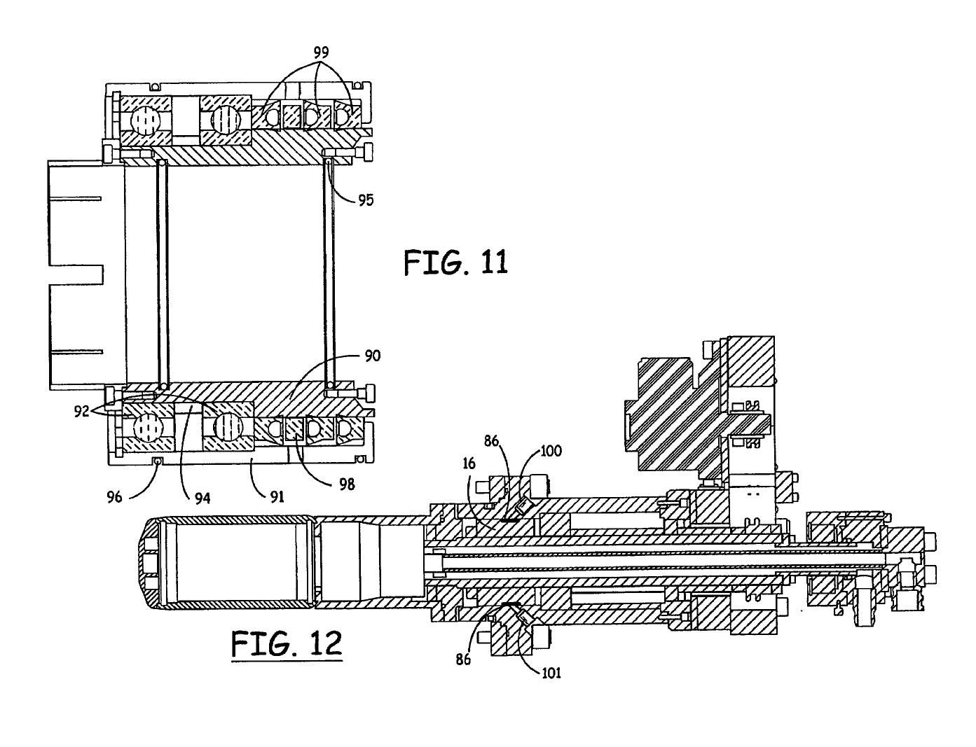

Reference is next made to FIGS. 9, 10 and 11 showing various further embodiments of a bearing/seal usable in the magnetron assembly of the present invention, with FIGS. 9 and 10 being ferro fluidic bearing/seals and FIG. 11 being a bearing/seal with a lip seal replacing the ferro fluidic liquid.

Specifically, FIGS. 9 and 10 show a ferro fluidic bearing/seal having an inner shaft 78 which rotates with the drive shaft 12,36 (FIGS. 1 and 2), an outer seal housing 79 which is fixed to the main housing 11,35 (FIGS. 1 and 2) and a pair of laterally spaced ball bearings 80. The inner shaft 78 includes a pair of laterally spaced, radially extending portions 81 for supporting the seal magnet 82 and accommodating the ferro fluidic liquid 84 at their peripheral edges. A pair of O-rings are provided between the inner shaft 78 and the drive shaft 12,36.

The outer peripheral surface of the seal housing 79 is provided with a water channel or groove 86 which extends around the entire periphery of the housing 79 in the area of the magnet 82 and the ferro fluidic liquid 84. As described below, when the bearing/seal of FIG. 9 is in use, the water channel or groove 86 forms a water flow path with the inner surface of the housing 79. This flow path is in communication with a source of cooling water to cool the ferro fluidic bearing/seal and in particular the ferro fluidic seal portion. A plurality of O-rings are provided between the outer surface of the seal housing 79 and the inner surface of the main housing 11,35. Two of these O-rings 88,88 are on opposite sides of the water channel 86 to confine the cooling water within the channel 86. In this embodiment, the provision of the cooling water channel 86 cools the bearing/seal in a magnetron assembly and thus eliminates or substantially reduces the impact of inductive heating.

The embodiment of FIGS. 10A and 10B differ from the embodiment of FIG. 9 in that the embodiment of FIGS. 10A and 10B includes a brush assembly comprising a plurality of electrically conductive brushes 89 positioned around an outer peripheral surface portion of the inner shaft 78. The brushes 89 are retained by threaded members 87. The brushes 89 function to electrically connect the inner shaft 78 and the seal housing 79 to provide a low resistance current flow path to preferably direct flow of stray or induced eddy currents between the seal housing 79 and the inner shaft 78 rather than through the bearings 80.

The bearing/seal embodiment of FIG. 11 includes an inner shaft 90 connectable with the drive shaft 12,36 (FIGS. 1 and 2), an outer seal housing 91 for connection with the main housing 11,35 (FIGS. 1 and 2) and a pair of ball bearings 92,92. A pair of O-rings 95 are positioned between the inner shaft 90 and the drive shaft and a pair of O-rings 96 are positioned between the seal housing 91 and the main housing. A bearing spacer 94 is positioned between the laterally spaced ball bearings 92. A plurality of lip seals 99 are provided between an outer peripheral surface of the shaft 90 and an inner peripheral surface of the seal housing 91 to form the vacuum seal between such elements. These lip seals 99 are connected with the shaft 90 and bear against the inner surface of the housing 91 during rotation. A grease ring 98 is positioned between two of the lip seals 99 which face one another. In the embodiment of FIG. 11, inductive heating is eliminated or substantially reduced by substituting the lip seals 99 for the conventional ferro fluidic seals of FIGS. 9 and 10. Bearing degradation resulting from stray or induced eddy currents is eliminated or substantially reduced in the embodiments of both FIGS. 9 and 11 by constructing either the bearing balls or one of the bearing races from an electrically non-conducting material, by constructing either the inner shaft 78 or 90 or the outer seal housing 79 or 91 from an electrically non-conductive material or by providing a non-conductive coating to either the inner or outer surface of the shaft 78 or 90 or the housing 79 or 91.

FIG. 12 is a view similar to that of FIG. 1 except that the embodiment of FIG. 12 includes a water cooling inlet port 100 and a water cooling outlet port 101. These water cooling ports 100 and 101 are in communication with the water cooling channel 86 of the bearing seal 16 as shown. The water cooling channel 86 extends around the peripheral surface of the bearing seal 16. Thus, cooling water flowing into the port 100 flows into the water cooling channel 86, around the bearing seal 16 in both directions and out through the outlet port 101. The cooling water may be obtained from an independent source or as part of the cooling water provided to the water cooling assembly or union 29,41 (FIGS. 1 and 2).

Although the description of the preferred embodiment has been quite specific, it is contemplated that various modifications could be made without deviating from the spirit of the present invention. Accordingly, it is intended that the scope of the present invention be dictated by the appended claims rather than be the description of the preferred embodiment.

1. A magnetron assembly comprising:
a housing;
a rotatable drive shaft mounted for rotation within said housing;
a target connected with said drive shaft;
a bearing between said housing and said drive shaft wherein at least a portion of said bearing is constructed of an electrically conductive material; and
means for substantially preventing any electrical current flow through said bearing.

2. The magnetron assembly of claim 1 wherein said means includes at least one of said inner race, said outer race and said bearing member being constructed of an electrically non-conductive material.

3. The magnetron assembly of claim 1 wherein said bearing includes an inner race, an outer race and a bearing member between said inner race and said outer race and wherein said means includes an electrically non-conductive coating applied to at least one of the outer surface of said outer race or the inner surface of said inner race.

4. The magnetron assembly of claim 1 wherein said means includes at least one of a sleeve of an electrically non-conductive material positioned between said bearing and said housing or a sleeve of an electrically non-conductive material positioned between said bearing and said drive shaft.

5. The magnetron assembly of claim 1 wherein said means includes at least one of a coating of an electrically non-conductive material applied to the outer surface of said drive shaft in the area of said bearing or a coating of an electrically non-conductive material applied to the inner surface of said housing in the area of said bearing.

6. The magnetron assembly of claim 1 wherein said bearing is a combination bearing/seal member comprising:
an outer bearing housing fixed relative to said housing;
an inner bearing connected with said drive shaft for rotation therewith;
a bearing member between said outer bearing housing and said inner bearing housing; and
a ferro fluidic seal between said outer bearing housing and said inner bearing housing.

7. The magnetron assembly of claim 6 wherein said means includes at least one of said outer bearing housing or said inner said bearing housing being constructed of an electrically non-conductive material.

8. The magnetron assembly of claim 6 wherein said bearing member includes an inner race, an outer race and a second bearing member between said inner race and said outer race and wherein said means includes at least one of said inner race, said outer race and said second bearing member being constructed of an electrically non-conductive material.

9. The magnetron assembly of claim 6 including a cooling fluid channel located between and defined by an inner surface portion of said housing and an outer surface portion of said bearing housing.

10. The magnetron assembly of claim 9 wherein said housing includes cooling fluid inlet and outlet ports in communication with said cooling fluid channel.

11. The magnetron assembly of claim 1 wherein said drive shaft extends in an axial direction and wherein said means includes an electrically conductive material in close association with said bearing and extending between said housing and said drive shaft.

12. The magnetron assembly of claim 9 wherein said electrically conductive member is an electrically conductive brush.

13. The magnetron assembly of claim 1 wherein said bearing is a combination bearing/seal member comprising:
an outer bearing housing fixed relative to said housing;
an inner bearing connected with said drive shaft for rotation therewith;
a bearing member between said outer bearing housing and said inner bearing housing; and
a lip seal between said outer bearing housing and said inner bearing housing.

14. A magnetron assembly comprising:
a housing;
a rotatable drive shaft mounted for rotation within said housing;
a target connected with said drive shaft;
a bearing between said housing and said drive shaft wherein said bearing includes an inner race, an outer race and a bearing member between said inner race and said outer race and wherein said bearing is packed with a conductive grease.

15. A combination bearing/seal for a magnetron assembly of the type comprising a housing, a rotatable drive shaft mounted within said housing, a cathode connected with the drive shaft and the combination bearing/seal positioned between said housing and said drive shaft, said combination bearing/seal comprising:
an outer bearing housing connectable with the magnetron assembly housing;
an inner bearing housing connectable to the magnetron assembly drive shaft for rotation therewith;
a ferro fluidic seal between said outer bearing housing and said inner bearing housing;
a bearing member positioned between said outer bearing housing and said inner bearing housing; and
means for substantially preventing any electrical current flow through said bearing member.

16. The combination bearing/seal of claim 15 wherein said means includes at least one of said outer bearing housings or said inner bearing housing being constructed of an electrically non-conductive material.

17. The combination bearing/seal of claim 15 wherein said bearing member includes an outer race, an inner race and a second bearing member positioned between said outer race and said inner race and wherein at least one of said inner race, said outer race and said second bearing member is constructed of an electrically non-conductive material.

18. The combination bearing/seal of claim 15 including a cooling fluid channel in an outer surface portion of said outer bearing housing.

19. A magnetron assembly comprising:
a housing;
a drive shaft for rotation within said housing;
a target connected with said drive shaft;
a bearing between said housing and said drive shaft wherein said bearing includes an inner race, an outer race and a bearing member between said inner race and said outer race and wherein at least one of said inner race, said outer race and said bearing member is constructed of an electrically non-conductive material and at least one of said inner race, said outer race and said bearing member is constructed on an electrically conductive material.

20. The magnetron assembly of claim 19 wherein each of said inner race and said outer race is constructed of an electrically conductive material and said bearing member is constructed of an electrically non-conductive material.

21. The magnetron assembly of claim 20 wherein said bearing member is constructed of ceramic.
